(19) United States
(12) Patent Application Publication
(10) Pub. No.: US 2024/0389668 A1
(43) Pub. Date: Nov. 28, 2024

(54) Electronic Cigarette

(71) Applicant: Carnault AG, Basel (CH)

(72) Inventors: Michael Schwitzer, Lichtenau (DE); Daniel Bock, Chemnitz (DE); Tobias Kaiser, Basel (CH)

(21) Appl. No.: 18/570,591

(22) PCT Filed: Jun. 14, 2021
(86) PCT No.: PCT/EP2021/065981

§ 371 Date: Jul. 15, 2024

(30) Foreign Application Priority Data
Jun. 18, 2020 (WO) PCT/EP2020/067041
Aug. 13, 2020 (WO) PCT/EP2020/072784
Sep. 17, 2020 (WO) PCT/EP2020/076045
Sep. 21, 2020 (WO) PCT/EP2020/076325

(51) Int. Cl. A24F 40/51; A24F 40/40; H05K 1/18

(52) U.S. Cl. CPC A24F 40/51; A24F 40/40; H05K 1/183; H05K 2201/10151

(57) ABSTRACT

An electric cigarette (1) according to the invention comprises a cartridge unit (2) and a control unit (3) detachably arranged thereon, wherein the electric cigarette (1) terminates at a first end with a mouthpiece end (25) and at a second end with a charging tip (4). Over the entire longitudinal extension along a Z-axis, the electric cigarette (1) has a cylindrical or polygonal cross-section and furthermore a first and/or a second and/or a third control element body (5) with a respective body diameter (6a, 6b, 6c) perpendicular to this Z-axis, wherein the respective body diameter (6a, 6b, 6c) of the respective control element body (5) forms a snug fit in the electric cigarette (1), and wherein the respective control element body (5) is further designed as a printed circuit board structure (17) with at least one printed circuit board (33) insulated by means of an insulating filling (32), which is aligned transversely to the Z-axis and on which at least one pressure sensor (30) is arranged, which is operatively connected to a cavity (41) in the printed circuit board structure (17).

### FIELD OF THE INVENTION

The present invention falls within the field of daily living and relates to an electric cigarette according to the general term of claim 1.

### STATE OF THE ART, TECHNOLOGICAL BACKGROUND OF THE INVENTION

Conventional electronic cigarettes are handy devices that use electrical energy to produce an inhalable aerosol from a precursor composition. For this purpose, each electric cigarette has at least the following functional elements: an energy source, electronic control components, a precursor composition and an aerosolization unit. The latter may consist of a heating element, e.g. a filament or a heating chip, or another assembly which can convert the precursor composition into an aerosol, e.g. by means of an ultrasonic atomizer, or by means of a single- or dual-substance atomizer nozzle. The precursor composition can either consist of a liquid or contain solid components, such as prepared tobacco products (so-called heat-not-burn products).

Electronic cigarettes are designed to be used in the same way as traditional tobacco cigarettes. A usage scenario, which is the rule when using a traditional tobacco cigarette and is therefore within the realm of expectation for electronic cigarettes, would consist of inhaling the aerosol produced by the electronic cigarette several times in succession with short pauses between each puff. Such a process, whereby the electronic cigarette is usually held in the hand, brought to the mouth and finally the aerosol is inhaled in the form of a kind of mist or vapor and exhaled again in parts, is also influenced by a desired visibility and perceptibility to outsiders. Smoking traditional tobacco cigarettes was and is heavily advertised in many parts of the world. Attempts have been made to associate it with positive values such as sociability, authenticity and freedom. The global success of traditional tobacco cigarettes, which is expressed in the high number of consumers of more than one billion people, could be a sign that this attempt has been at least partially successful. The fact that the smoking of tobacco cigarettes is extremely widespread, but not the use of similar, often cheaper and in some cases far less harmful nicotine-containing products such as oral tobacco, suggests that it is precisely the high visibility and perceptibility of the smoking process and the product that has a significant influence on its success and its ability to be associated with positive values.

These considerations lead to the conclusion that the success of an electronic cigarette is also highly dependent on the external perception of the product itself and on the external perception during use of the product. In the same sense, it is also reasonable to conclude that the design is also decisive for the question of the extent to which an electronic cigarette can be credibly associated with the very values that have helped tobacco cigarettes to achieve their success. It should be noted that these values described above can be described as timeless, at least to the extent that they are fundamental values for people that are discussed extensively and intensively in almost every culture and can be assumed to remain relevant in the future. The product design is therefore a key differentiating feature compared to both other electronic cigarettes and traditional tobacco cigarettes and may be the only distinguishing criterion that is visible to the outside world. Consequently, it can be a decisive advantage for success if an electronic cigarette is characterized by one or more of the following aspects, namely a high-quality choice of materials for the externally visible components, a high quality of workmanship, a long service life, possibilities for individualizing the external design, for example through the interchangeability of components, a small product size that is conducive to a pleasant feel and easy handling. The dimensions should be as close as possible to the shape and size of a classic tobacco cigarette, as it can be assumed that many people are used to the shape and size of classic tobacco cigarettes and their weight. Furthermore, aspects such as environmental friendliness, waste minimization, recyclability and waste separation of materials are important today. The same applies to the choice of materials. Selected materials, such as wood or ebonite, are well known to smokers from cigarette-related products such as tobacco pipes, which means that the use of such materials in electronic cigarettes could also create a familiarity among smokers.

Furthermore, control electronics in the electronic cigarette should ensure reliable and safe functioning of the aerosol generation and, if necessary, include extended functions, such as the possibility of a Bluetooth connection to a smartphone or authentication of the consumable in a so-called cartridge and also a quantity control; the extended range of functions is directly associated with an increased space requirement for electronic components or for electronic components, e.g. for more complex circuit structures in and around integrated circuits [IC]. In addition, such control electronics include a switch-on element in the form of a switch, button or sensor that is able to register a customer's air flow (e.g. pressure sensor, air flow sensor, temperature sensor), as well as display elements, such as an LED, and components for evaluation. Furthermore, the modularity of electronic cigarettes is advantageous for the purpose of replacing individual components in the event of further developments and improvements or in the event of damage. This requires various interfaces and contacts, which may require additional space.

In a rechargeable battery cell, a high retrievable current and the highest possible usable capacity are advantageous as an energy source, whereby this is accompanied by the positive correlation between battery capacity and maximum discharge current, as well as the usually unfavorable positive correlation between capacity, maximum discharge current and a correspondingly large volume or a correspondingly large mass of such a rechargeable battery cell.

Of course, with a view to low production costs, economic aspects are not disregarded, which are based on simple assembly, inexpensive components, the most cost-effective and thus optimized size or a high degree of automation.

Some of the above-mentioned requirements for electronic cigarettes are in conflict with each other and therefore require a balance to be struck between the advantages that must be fulfilled and the associated secondary disadvantages.

For example, the use of natural materials such as wood or ebonite means that a certain minimum wall thickness for stability cannot be undercut, which is greater than that of stainless steel or other metals and alloys, so that tubes made of wood or ebonite, for example, require more space. In order to remain as true as possible to the shape and size of a tobacco cigarette and at the same time to be able to realize a technically advanced electric cigarette, this makes a space-saving design unavoidable.

Furthermore, a circular-cylindrical housing shape, for example, means that the battery cell must also be circular-cylindrical in order to fit optimally into this shape. However, at least for small cell sizes, rectangular battery cells with the same volume can be realized with a higher capacity than circular-cylindrical battery cells. This is due to the basic layer structure of battery cells. In a round cell, the electrode and separator layers are usually rolled up, resulting in an unused cavity in the middle due to the limited angle of curvature of the layers used. This makes the efficient use of installation space in a circular cylindrical housing even more important. A cuboidal housing structure also benefits the design of printed circuit boards. A flat and rectangular PCB shape can be realized more easily without sacrificing size or functionality and at the same time can be integrated into a cuboid housing in a space-efficient manner. The electronic components with which the PCB of a control unit is equipped are often rectangular themselves, so they can be arranged more efficiently on a rectangular PCB surface than on a round one. A rectangular housing is therefore more suited to the design of battery cells and PCBs than a circular-cylindrical housing would be and would, for example, simplify the conflicting goals of small product size, the most powerful battery cell possible and good space utilization of the PCB. As a result, however, one moves away from the goal of similarity to the tobacco cigarette.

In terms of sustainability and cost-effectiveness, the use of high-quality materials or investment in high-quality workmanship only makes sense if the corresponding components have a certain durability. Consequently, it would be a disadvantage if the service life of a battery case, which takes up the largest part of the visible surface when the electronic cigarette is assembled and represents a central design object, were linked to the comparatively limited service life of the battery cell located inside it if both parts were permanently connected to each other. To achieve high processing quality and the use of high-quality materials, particularly in the area of the battery case, in a sustainable and economically viable manner, a modular, separable design of the control electronics or control unit, the battery cell and the battery case is a prerequisite. A high degree of modularity regularly conflicts with a small product size, as the individual parts must have separable mechanical and electrical connections, which generally take up additional space. Furthermore, as higher demands are placed on the design, it can become more complex: more and/or more complex components may be required or a greater number of work steps may be needed for production, which would have a negative impact on final assembly and production costs.

The most powerful battery cells possible stand in the way of the highest possible functionality of the control electronics and a small product size. Simple assembly of the electronic cigarette can conflict with increasingly complex control electronics, which sometimes results in the use of flexible circuit boards or various wiring and additional parts for connecting the circuit board to the housing, such as injection-molded parts, etc.

Simple technical operation can also have a negative impact on space requirements and product size, and it is also desirable for the electronic cigarette to remain in an assembled and quasi-functional state while the battery is charging. Such charging capability may take up additional space in contrast to a permanent cap, which does not provide any additional functions, for example because additional wiring may be required. Increased functionality or electrical design requirements can also lead to increased space requirements. For example, the detection of changes in air pressure or air flow during the smoking process, so that the electronic cigarette can be used in the same way as a tobacco cigarette, makes air flow management necessary. This often requires additional components in addition to a pressure sensor.

An electric cigarette is known from publication WO 2019/104441 A1, which uses a mass air flow meter to measure pressure. In the present case, the air mass meter has an upstream input connection and a downstream input connection. The mass air flow meter can contain a pressure sensor element, which is arranged between the upstream connection and the downstream connection. The pressure sensing element may determine the mass of air being drawn past the upstream port and the downstream port by determining the pressure difference between the upstream port and the downstream port. In the same cases, a thermal hot-wire anemometer or a solid-state hot-wire air mass sensor can be used for the air mass sensor. In other cases, individual barometric pressure sensors may be provided at each of the upstream port and downstream port. A difference between the barometric pressure sensors—resulting from the pressure drop element within the fluid channel—can be used to determine the mass air flow.

### REPRESENTATION OF THE INVENTION

It is therefore the task of the present invention to further develop an electric cigarette in such a way that, utilizing all the advantages of known electric cigarettes (with or without harmful substances, curative or medical additives, cessation agents, pure vapor without additives . . . ), a simplified structure with a high degree of modularity is made possible and, compared to conventional electric cigarettes, a smaller design is made possible and an extended, safe and durable functionality, in particular also with regard to air flow management, for which a pressure sensor is often used.

The problem underlying the invention for the electric cigarette is solved by the features of claim 1; the features further forming this inventive concept are each the subject of subclaims 2 to 10.

Advantageously, the electric cigarette according to the present invention has a cartridge unit and a control unit detachably arranged thereon along a central Z-axis from bottom to top, the electric cigarette terminating at a first end at the bottom with a mouthpiece end and at a second end at the top with a charging tip, and wherein this electric cigarette has a cylindrical or polygonal cross-sectional area over its entire length and comprises a first and/or a second and/or a third control element body with a respective body diameter perpendicular to the central Z-axis and wherein this respective body diameter is selected in such a way that the respective control element body forms a tight fit in the interior with the electric cigarette and wherein the respective control element body is further designed as a printed circuit board structure with at least one printed circuit board which is insulated by means of an insulation filling and which is aligned transversely to the Z-axis, and wherein at least one pressure sensor is arranged on this printed circuit board and is operatively connected to a cavity in the printed circuit board structure.

Compared with the prior art, the electric cigarette according to the invention stands out from the prior art with its cylindrical or polygonal cross-sectional area and its compact structure and in particular with its compact and protected arranged pressure sensor; furthermore, the arrangement of the control element body by means of a fit in the electric cigarette enables a significantly improved use of space within this electric cigarette and also a significantly higher degree of modularity, since each control element body is designed to be non-destructively replaceable if required or desired.

In a particularly advantageous embodiment of the invention, the control element body is designed as a control unit which is arranged between the cartridge unit and the control unit with the interference fit and closes off the control unit towards this cartridge unit. This arrangement of the control unit is advantageous due to its central position between the control unit and the cartridge unit, since it is thus possible to intervene directly on both units, namely the control unit and the cartridge unit, in a controlling or regulating manner.

A particularly advantageous embodiment of the invention is characterized in that the at least one pressure sensor with the at least one printed circuit board is designed as an integrated electronic component embedded in the printed circuit board structure. Furthermore, the pressure sensor can advantageously be completely surrounded by the cavity, with the exception of its direct, also electrical, printed circuit board connection; in this embodiment, the cavity can on the one hand be closed to the outside directly by means of the insulating filling, or the pressure sensor surrounded by the cavity can initially be covered by a cap, whereby this cap can be fixed to the outside by means of the insulating filling. The advantage of using the cap or a hood is that it is more dimensionally stable than the insulation filling and the cavity can therefore be limited in a defined manner. It can also be advantageous if, in a further embodiment of the invention, the pressure sensor is partially surrounded by the insulation filling next to the cavity; this provides a compact, stable and firm connection between the printed circuit board and the pressure sensor. In a further advantageous embodiment of the invention, it is provided that the cavity in the pressure sensor is intrinsically designed or is itself arranged therein and this pressure sensor together with the cavity is integrated into the printed circuit board structure.

Various prior art processes can be used to manufacture the cavity. In the present case, the printed circuit board structure is manufactured closed with all embedded, integrated electronic components inside, if applicable, and then the opening to the cavity is made so that the pressure sensor in the cavity can enter into active contact with pressure changes in the air flow of the electronic cigarette through this opening. Conventional processing methods for the printed circuit board materials or insulation materials, such as mechanical drilling, laser drilling, etching, etc., can be used to create the opening.

In view of the desired high degree of modularity, it is particularly advantageous if the fit of the control element body formed between the electric cigarette is designed as a clearance fit, whereby the control element body is arranged so that it can just be displaced slightly, or if the fit of the control element body formed with the electric cigarette is designed as a transition fit, whereby the control element body is arranged so that it can be displaced with little pressure. In any case, the arrangement with a snug fit enables at least the most exact possible positioning of each control element body in the electric cigarette with the smallest possible space requirement and, in the case of the transition fit, also a desired degree of fixability.

Of course, it is also conceivable within the scope of the present invention to integrate the at least one pressure sensor or a further pressure sensor in the printed circuit board structure of the charging tip control and/or the cartridge control.

Further advantageous embodiments are highlighted with reference to the following figures in connection with the detailed description of the invention.

### BRIEF DESCRIPTION OF THE FIGURES

In the following, the invention is explained by way of example with the aid of figures. Identical objects are generally provided with the same reference signs in the figures. At this point, it should be noted that the figures have no restrictive effect whatsoever on the object of the invention, but merely represent possible embodiments of the inventive concept.

It shows purely schematically the

FIG. 1 a longitudinal sectional view of an electric cigarette according to the invention with a central Z-axis for the purpose of a simple description when locating individual elements of the electric cigarette by means of the terms “top”, “bottom”, “upwards”, “downwards”, “upper end”, “lower end”, “upper side”, “underside”, which are also partly used here in the figures; in addition, an enlarged longitudinal sectional view of a cartridge unit of this electric cigarette is shown;

FIG. 2 a cross-sectional view of a control element body of the electric cigarette using the example of a control unit which is designed as a printed circuit board structure;

FIG. 3 an embodiment of the cross-sectional view of the control element body of the electric cigarette using the control unit as an example;

FIG. 4 a further embodiment of the cross-sectional view of the control element body of the electric cigarette using the control unit as an example; and

FIG. 5 another embodiment of the cross-sectional view of the control element body of the electric cigarette using the example of the control unit, which is designed as a printed circuit board structure.

### WAYS TO CARRY OUT THE INVENTION

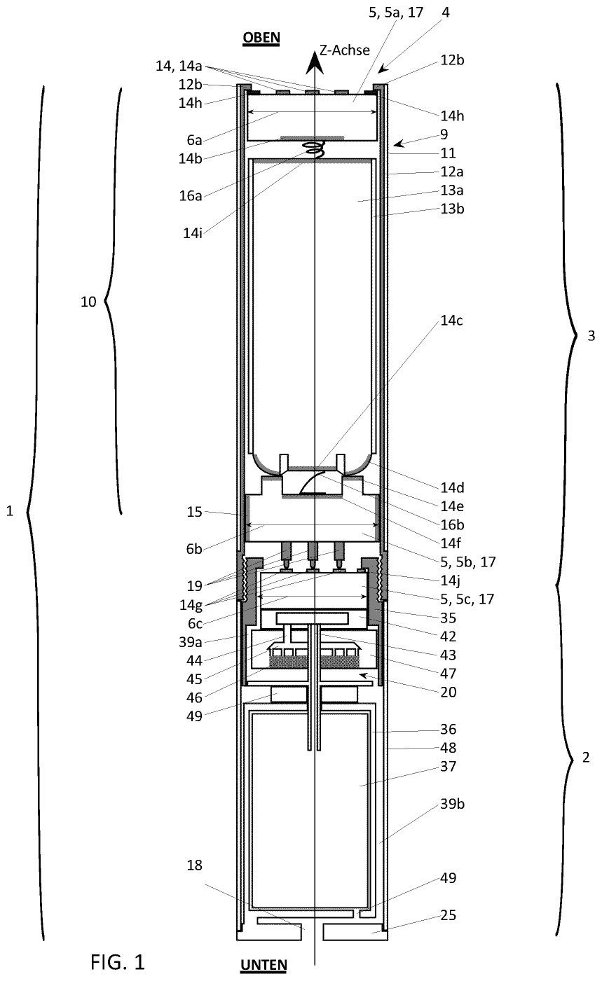

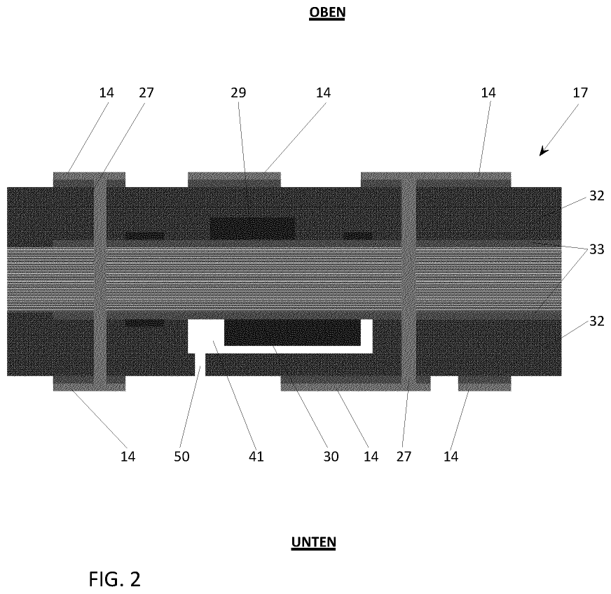

FIG. 1 shows a longitudinal sectional view of an electric cigarette 1 according to the invention. The electric cigarette 1 is shown here with a central Z-axis with an arrowhead at the upper end for the purpose of a simple description when locating individual components of the electric cigarette 1 by means of the terms “top”, “bottom”, “upwards”, “downwards”, “upper end”, “lower end”, “upper side”, “underside”, etc., which are also partly used here in the figures. In the present case, the electric cigarette 1 according to the invention comprises, from bottom to top, a cartridge unit 2 and a control unit 3 detachably arranged thereon, the charging tip 4 being arranged at an end of this electric cigarette 1 remote from the cartridge unit 2. This charging tip 4 has several electrical contact surfaces 14, 14a, which can be contacted for the purpose of charging the electronic cigarette 1 and/or for the purpose of exchanging data with the electronic cigarette 1. The charging tip 4 comprises a control element body 5, which is designed here as a charging tip control 5a with a body diameter 6a perpendicular to the central Z-axis, this body diameter 6a being selected such that the charging tip control 5a forms a tight fit with the electronic cigarette 1. With this type of design, the greatest possible space utilization with the smallest possible space requirement of the charging tip control 5a is made possible, particularly regarding the body diameter 6a, which is also equipped with the electrical contact surfaces 14, 14a, 14b at the top or bottom. In the present case, the charging tip control 5a is designed as a printed circuit board structure 17, which will be discussed below, in particular with the aid of FIGS. 2 to 5. The charging tip 4 is associated with a battery unit 10, which has a battery 13a with a surrounding battery insulation 13b in a battery sleeve 9, which battery 13a has an electrical contact surface 14i facing upwards towards the charging tip control 5a or towards its lower electrical contact surface 14b, a connecting spring contact 16a being arranged between these two electrical contact surfaces 14b, 14i.

The battery sleeve 9 has a conductive inner tube 12a and is surrounded on the outside by an insulating outer tube 11. At the lower end, the conductive inner tube 12a is closed with a control element body 5 designed as a control unit 5b, which control unit 5b has upward contact surfaces 14f and 14e which are connected to lower contact surfaces 14c, 14d of the battery 13a, with a spring contact 16b bridging the contact surfaces 14c and 14f. The control element body 5 of the control unit 5b has a body diameter 6b, which also forms a tight fit with the electric cigarette 1.

The lower end of the control unit 5b is equipped with a number of contact pins 19, which are electrically connected to contact surfaces 14g of the cartridge unit 2. Like the charging tip control 5a, the control unit 5b is also advantageously designed as a printed circuit board structure 17, which will be discussed later. It is particularly advantageous that the charging tip control 5a is electrically connected via the conductive inner tube 12a of the battery sleeve 9 and by means of a sheath surface contact 15 of the control unit 5b or to a further control element body 5 in the cartridge unit 2, whereby this further control element body 5 is designed here as a cartridge control 5c. By means of these electrical active connections, a continuous data exchange can also take place via the charging tip control 5a, the control unit 5b or the cartridge control 5c in addition to the charging of the electronic cigarette 1, which can include switching commands, for example, or parameterization data or programming data. The control element body 5 of the cartridge unit 5c has a body diameter 6c, which also forms a tight fit with the electronic cigarette 1, in this case with a cartridge end 35.

In the present embodiment of the invention, the cartridge unit 2 comprises a reservoir housing 36, which is provided at the top with the cartridge closure 35 and cartridge control 5c arranged therein and is filled with an aerosol precursor composition 37; at the bottom, a mouthpiece end 25 with a mouthpiece opening 18 closes the reservoir housing 36.

The control element bodies 5 positioned with a fit, namely the charging tip control 5a, the control unit 5b and the cartridge control 5c, can optionally be arranged in the electronic cigarette 1 in two different ways, on the one hand with a so-called transition fit and on the other hand with a clearance fit. In the present case, the control unit 5b with its lateral surface contact 15 is fixed in the inner tube 12a by means of a transition fit and can therefore only be displaced therein with slight pressure, whereas the charging tip control 5a, which is supported upwards against a flange 12b, forms a clearance fit with the inner tube 12a and can therefore be easily displaced therein.

In the present case, the cartridge unit 2 comprises, in addition to the cartridge control unit 5c, a micropump 42 and subsequently a heating chip 47. The micropump 42 serves, for example, the aerosol precursor composition 37 via a hollow needle 43 from a reservoir housing 36. This cartridge unit 2 comprises, by way of example, two groups of parts, one group of parts being detachably arranged on the electronic cigarette 1 and also remaining there, and the other group of parts being designed as a consumable for replacement after consumption. The first group of parts, which remains on the electronic cigarette 1 even after it has been used, comprises the cartridge end 35 with the cartridge controller 5c, the micropump 42 and the heating chip 47 surrounded by the cartridge case 48 and the needle 43; the second group of parts essentially comprises the reservoir housing 36 inserted in the cartridge case 48 with the aerosol precursor composition 37 and the mouthpiece end 25. After use of the electric cigarette 1, only the second group of parts is replaced as a unit, whereby after insertion into the cartridge case 48, the aerosol precursor composition 37 can be sucked in by the micropump 42 through this needle 43 in order to then be passed on via a feeder 44 to a distributor 45 and finally to a distributor substrate 46 in the heating chip 47. Air flowing from an air channel 39a to an aerosolization zone 20 is provided there with an aerosol from the aerosol precursor composition 37 via the air channel 39b to a consumer at the mouthpiece opening 18.

As already mentioned above, the charging tip controller 5a, the control unit 5b and the cartridge controller 5c can advantageously be designed as a printed circuit board structure 17, as shown in more detail in FIGS. 2 to 5. This printed circuit board structure 17 can have one or more of the functions of the electronic cigarette 1 listed below, namely an air volume measurement, a residual volume determination for an aerosol precursor composition 37, a charge level determination of the battery 13a, an authentication device or a communication device (RFID, Bluetooth, . . . ), possibly for a data exchange with a smartphone or a smartwatch, whereby this list of functions is not to be regarded as exhaustive.

FIG. 2 now shows an exemplary embodiment of the printed circuit board structure 17 of the control unit 5b (FIG. 1), with several electrical contact surfaces 14 on the upper side or on the lower side thereof; for the sake of simplicity, all contact surfaces—not as shown in FIG. 1—are merely provided here with a general reference sign “14”. The circuit board structure 17 shown here also comprises, in simplified form, a number of conductor tracks or vias 27 as well as a number of integrated structures such as a microcontroller 29 and a pressure sensor 30, which are arranged on circuit boards 33 insulated from one another by means of insulation fillings 32. By means of such a printed circuit board structure 17, a large number of functions of the electric cigarette can be mapped, whereby further structures can be added or omitted if necessary. Without departing from the idea of the invention, it is of course also conceivable that further functions are integrated in this printed circuit board structure 17, which are not explicitly mentioned here.

In the present case, FIG. 2 discloses a possible embodiment of the printed circuit board structure 17 in a greatly enlarged sectional view. In its simplest form, this printed circuit board structure 17 comprises at least one printed circuit board 33, which is equipped with a pressure sensor 30 and a microcontroller 29 as integrated components. An exemplary structure based on embedded electronic components is shown here. In this embedding technology variant shown here, the components that will later be located inside are soldered onto the respective copper layer, which is structured by etching, for example, using a soldering process and covered by cover layers made of an insulating filling or printed circuit board material 32 (prepregs) in the subsequent printed circuit board manufacturing process. The copper layers onto which the components are soldered can either be individual foils or, as in the case shown, part of prepared two- or multi-layer PCBs consisting of at least one insulator, e.g. a hardened prepreg 32 and two pressed-on copper layers. Depending on the design and the choice of material, the resin in the cover layer materials, for example, is used during the subsequent PCB pressing process to fill free spaces around the embedded components.

Other embedding technologies are available that also enable the processing of non-housed active electronic components, such as microcontrollers or ASICs, without an extra soldering process. With these technologies, standard processes from the PCB industry, e.g. micro-drilling (HDI technology, microvias) and electroplating, are used for the component contacting of the electronic components that are later placed inside. However, the basic structure with embedded components remains largely the same regardless of the embedded variant selected. Multilayer PCBs with embedded components can also be produced using 3D printing/additive processes, e.g. on a paste/lacquer basis with drying or curing with UV light.

In addition to embedding electronic components, the use of PCB technology suitable for large-scale production also enables complex 3D structuring of the resulting assembly using standard machining processes with high precision and low tolerances. Mechanical guides and additional external contact elements can be realized very easily in final PCB processes.

The various layers of the multilayer PCB with embedded electronic components are connected to each other using through-hole plating 27 (microvias, vias) in a standard PCB process and secure the electrical connections in the Z-axis of the compact assembly.

A printed circuit board structure 17 designed in this way is characterized not only by improved miniaturization but also by lower energy consumption and lower power loss compared to the prior art. In the present case, the printed circuit board structure 17 comprises several printed circuit boards 33 with embedded elements, such as the microcontroller 29 and the pressure sensor 30, which are merely intended here as examples of further equivalently equipped embodiments; typically, the printed circuit boards 33 arranged here horizontally and thus perpendicular to the Z-axis are spaced apart by insulation fillings 32, with conductor tracks or vias 27 partially or completely electrically connecting the printed circuit board structure 17.

In the present case, the printed circuit board structure 17 has a cavity 41 with the internal pressure sensor 30, whereby this pressure sensor 30 is completely surrounded by the cavity 41, with the exception of the direct, also electrical connection between the pressure sensor 30 and the printed circuit board 33. The cavity 41 has an opening 50, with which the pressure sensor 30 outside the cavity 41 enters into active connection with the air flow in the air ducts 39a, 39b of the electronic cigarette 1, see also FIG. 1. 1. Due to the fact that the pressure sensor 30 is only connected to the printed circuit board 33 and is otherwise arranged in the cavity 41 without contact, thermal and/or mechanical influences on the pressure sensor—for example from the insulating filling 32—can be largely avoided.

With particular advantage, the control unit 5b is designed as such a printed circuit board structure 17, whereby the pressure sensor 30 is in direct operative connection with the air duct 39, 39a or 39b, see also FIG. 1, in order to cause the electronic cigarette 1 to be switched on when suction is applied via the mouthpiece opening 18. The pressure sensor 30 can thus be designed as an embedded, integrated electronic component in this printed circuit board structure 17.

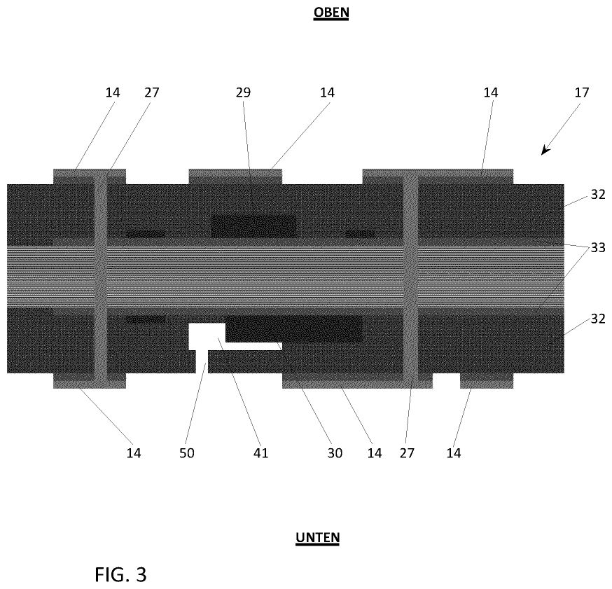

The further embodiment according to the invention shows in FIG. 3 an almost identical representation as in FIG. 2, with the difference that the pressure sensor 30 is partially surrounded by the insulation filling 32 in addition to the cavity 41. Here, taking into account any thermal or mechanical influences of the insulating filling 32 on the pressure sensor 30, an improved fixation of the pressure sensor 30 in the printed circuit board structure 17 is achieved compared to the embodiment in FIG. 2. Such an embodiment makes the pressure sensor 30 and thus the entire printed circuit board structure 17 insensitive to strong accelerations, which can occur, for example, if the electric cigarette is dropped.

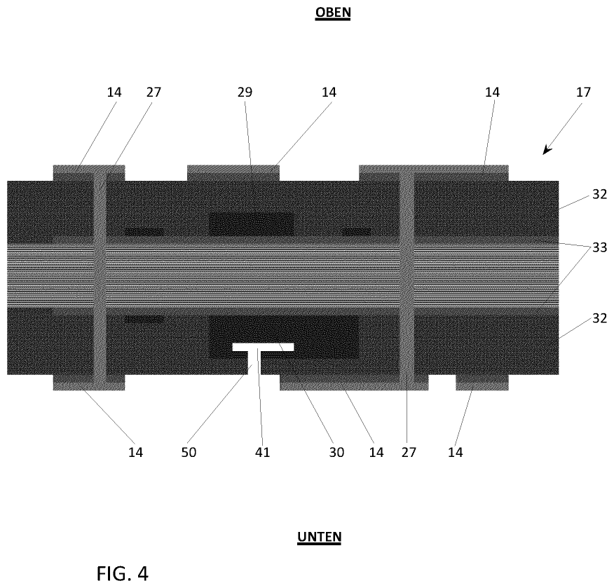

FIG. 4 shows a further embodiment according to the invention in which, in contrast to the embodiments in FIGS. 2 and 3, the cavity 41 is designed as an intrinsic component of the pressure sensor 30 and the pressure sensor 30 is otherwise completely surrounded by the insulating filling 32. This embodiment represents comparatively the most stable embodiment of the invention or the embodiment that is least sensitive to falls.

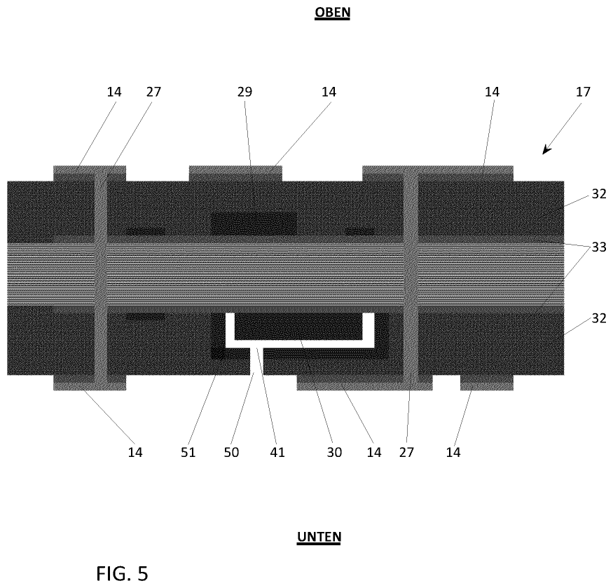

FIG. 5 shows a further embodiment of the invention, in which the pressure sensor 30—based on the embodiment in FIG. 1—is completely surrounded by the cavity 41, which itself is surrounded by a cap 51 or hood 51 in the insulating filling 32. In a dimensionally stable embodiment, this cap 51 can provide the best possible protection against any influences of the insulating filling 32 on the pressure sensor 30.

### LIST OF REFERENCE SYMBOLS

2 Cartridge unit
3 Control unit
4 Charging tip
5 Control element body
5a Charging tip control
5b Control unit
5c Cartridge control
6a, b, c Body diameter
9 Battery sleeve
10 Battery unit
11 Outer tube of the 9, electrically non-conductive
12a Inner tube of the 9, electrically conductive
12b Flange to 12a
13a Battery
13b Battery insulation
14, 14a, 14b, 14c, 14d, 14e, Electrical contact surface
14f, 14g, 14h, 14i, 14j
15 Outer surface contact
16a, 16b Spring contact
17 Printed circuit board structure
18 Mouthpiece opening
19 Contact pin
20 Aerosolization zone
25 Mouthpiece end
27 Through-hole plating
29 Microcontroller
30 Sensor, pressure sensor
32 Insulation filling
33 Printed circuit board
35 Cartridge end
36 Reservoir housing
37 Aerosol precursor composition
39, 39a, 39b Air duct
41 Cavity in 17
42 Micro pump
43 Needle
44 Feeder
45 Distributor
46 Distribution substrate
47 Heating chip
48 Cartridge case

1.-10. (canceled)

11. An electric cigarette terminating at a first end with a mouthpiece end and at a second end with a charging tip, the electronic cigarette comprising:
a cartridge unit and a control unit detachably arranged thereon,
wherein the electric cigarette has a cylindrical or polygonal cross-section over its entire longitudinal extent along a Z-axis and has one or more control element bodies having a respective body diameter perpendicular to the Z-axis, wherein this respective body diameter of a respective control element body forms a snug fit in the electric cigarette, and wherein the respective control element body is further designed as a printed circuit board structure with at least one printed circuit board insulated by means of an insulating filling, which is aligned transversely to the Z-axis;
wherein at least one pressure sensor is arranged on a first printed circuit board of the at least one printed circuit board, which is operatively connected to a cavity in the printed circuit board structure.

12. The electric cigarette according to claim 11, wherein the at least one pressure sensor is arranged on the first printed circuit board such that sides of the at least one pressure sensor that face away from the first printed circuit board are completely surrounded by the cavity.

13. The electric cigarette according to claim 11, wherein one of the control element bodies is designed as a control unit which is arranged between the cartridge unit and the control unit and closes off the control unit towards the cartridge unit.

14. The electric cigarette according to claim 11, wherein the at least one pressure sensor is formed with the at least one printed circuit board as an integrated electronic component embedded in the printed circuit board structure.

15. The electric cigarette according to claim 14, wherein the at least one pressure sensor is arranged on the first printed circuit board such that sides of the at least one pressure sensor that face away from the first printed circuit board are completely surrounded by the cavity.

16. The electric cigarette according to claim 15, wherein the cavity is surrounded by a cap embedded in the printed circuit board structure.

17. The electric cigarette according to claim 11, wherein the at least one pressure sensor is arranged on the printed circuit board to be partially surrounded by an insulating filling next to the cavity.

18. The electric cigarette according to claim 11, wherein the at least one pressure sensor in the printed circuit board structure intrinsically includes the cavity.

19. The electric cigarette according to claim 11, wherein the cavity is in an operative connection with an air channel in the electric cigarette by means of an opening.

20. The electric cigarette according to claim 11, wherein the fit of the respective control element body formed with the electric cigarette is designed as a clearance fit, and wherein the respective control element body is arranged to be slightly displaceable.

21. The electric cigarette according to claim 11, wherein the fit of the respective control element body formed with the electric cigarette is designed as a transition fit, wherein the respective control element body is arranged to be displaceable with low pressure.
